(19) United States
(12) Patent Application Publication
(10) Pub. No.: US 2009/0068342 A1
(43) Pub. Date: Mar. 12, 2009

(54) POSITIVE PHOTORESIST COMPOSITION, THICK FILM PHOTORESIST LAMINATE, METHOD FOR PRODUCING THICK FILM RESIST PATTERN, AND METHOD FOR PRODUCING CONNECTING TERMINAL

(75) Inventors: Takahiro Senzaki, Kawasaki-shi (JP); Koichi Misumi, Kawasaki-shi (JP); Koji Saito, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: TOKYO OHKA KOGYO CO., LTD., Kanagawa-ken (JP)

(21) Appl. No.: 11/915,134

(22) PCT Filed: Mar. 30, 2006
(86) PCT No.: PCT/JP2006/306674

§ 371 Date: Nov. 20, 2007

(30) Foreign Application Priority Data
May 24, 2005 (JP) 2005-151252

(51) Int. Cl. B05D 5/12; G03F 7/09; G03F 7/20

(52) U.S. Cl. 427/58; 430/285.1; 430/326

(57) ABSTRACT

The present invention provides a positive photoresist composition used to form a thick film resist pattern on a support which includes (A) a compound that generates acid on irradiation with active light or radiation, and (B) a resin that displays increased alkali solubility under the action of acid, wherein the component (B) includes a resin (B1) which has a structural unit (b1) derived from an acrylate ester, in which a hydrogen atom of a carboxyl group has been substituted with an acid dissociable, dissolution inhibiting group represented by represented by a general formula (I) shown below:

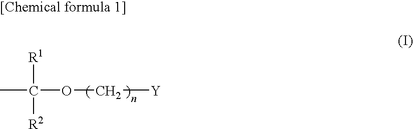

[wherein, Y represents an aliphatic cyclic group or an alkyl group which may have a substituent group; n represents either 0 or an integer from 1 to 3; R¹ and R² each independently represents a hydrogen atom or a lower alkyl group having 1 to 5 carbon atoms].

### TECHNICAL FIELD OF THE INVENTION

The present invention relates to a positive photoresist composition, thick film photoresist laminate, a method for producing a thick film resist pattern and a method for producing a connecting terminal.

The present application is based upon and claims the benefit of priority from the prior Japanese Patent Application No. 2005-151252, filed May 24, 2005, the entire contents of which are incorporated herein by reference.

### BACKGROUND OF THE INVENTION

Along with the size reduction of electronic instruments, the large scale integration of a semiconductor integrated circuit (LSI) has recently made rapid progress. To mount LSI in electronic instruments, a multi-pin thin film mounting method, is used, which provides a connecting terminal including an extruding electrode on the surface of a support such as substrate.

In the multi-pin thin film mounting method, a connecting terminal including a bump protruding from a support, or a connecting terminal comprising a pole brace, which is referred to as a metal post, protruding from a support and a solder ball formed thereon is used.

The bump or metal post can be formed, for example, by forming a thick film resist layer having a thickness of about 5 μm or more on the support, exposing to light through a predetermined mask pattern, developing to form a resist pattern in which a portion capable of forming a connecting terminal is selectively removed (peeled), embedding a conductor such as copper in the portion (non-resist portion) thus removed, and finally removing the resist pattern in the vicinity of the portion.

Positive photosensitive resin compositions including a compound containing a quinone diazide group have been disclosed as suitable thick-film photoresists for the formation of bumps or wiring (for example, see patent reference 1 below).

On the other hand, chemically amplified photoresists including an acid generator are known as photosensitive resin compositions with even better sensitivity than that provided by conventional photosensitive resin compositions including a compound containing a quinone diazide group.

The characteristic features of a chemically amplified photoresist are that on irradiation (exposure), acid is generated from the acid generator, diffusion of this acid is promoted by post exposure baking, and the base resin or the like of the resin composition then undergoes an acid-catalyzed reaction, thereby altering the alkali solubility of the reacted resin.

Chemically amplified photoresists include positive photoresists, in which irradiation causes alkali insoluble portions to become alkali soluble, and negative photoresists, in which irradiation causes alkali soluble portions to become alkali insoluble.

For example, a positive chemically amplified photoresist composition for plating is disclosed in patent reference 2 below.

Moreover, the inventors of the present invention have already found a positive chemically amplified photoresist composition for a thick film (for example, see patent reference 3 to 6 below).

(Patent Reference 1)

Japanese Unexamined Patent Application, First Publication No. 2002-258479

(Patent Reference 2)

Japanese Unexamined Patent Application, First Publication No. 2001-281862

(Patent Reference 3)

Japanese Unexamined Patent Application, First Publication No. 2004-309775

(Patent Reference 4)

Japanese Unexamined Patent Application, First Publication No. 2004-309776

(Patent Reference 5)

Japanese Unexamined Patent Application, First Publication No. 2004-309777

(Patent Reference 6)

Japanese Unexamined Patent Application, First Publication No. 2004-309778

### DISCLOSURE OF THE INVENTION

### Problems to be Solved by the Invention

In this field of a photoresist composition for a thick film, demands for higher sensitivity to radiation with regard to a photoresist composition are increasing. Therefore, conventional photoresist compositions for a thick film are also required to have improved sensitivity.

The present invention takes the above problems associated with the conventional technology into consideration with an object of providing a positive photoresist composition which can obtain high sensitivity when forming a thick film resist pattern, a thick film photoresist laminate using the same, a method for producing a thick film resist pattern, and a method for producing a connecting terminal.

### Means for Solving the Problem

In order to achieve the above object, the present invention adopts the aspects described below.

A first aspect of the present invention is a positive photoresist composition used to form a thick film resist pattern on a support which includes (A) a compound that generates acid on irradiation with active light or radiation, and (B) a resin that displays increased alkali solubility under the action of acid, wherein the component (B) includes a resin (B1) which has a structural unit (b1) derived from an acrylate ester, in which a hydrogen atom of a carboxyl group has been substituted with an acid dissociable, dissolution inhibiting group represented by the general formula (I) shown below.

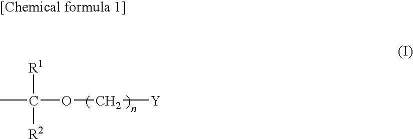

[wherein, Y represents an aliphatic cyclic group or an alkyl group which may have a substituent group; n represents either 0 or an integer from 1 to 3; R¹ and R² each independently represents a hydrogen atom or a lower alkyl group having 1 to 5 carbon atoms]

A second aspect of the present invention is a thick film photoresist laminate, wherein a support and a thick film photoresist layer with a film thickness of 10 to 150 μm including the positive photoresist composition in the present invention is laminated.

A third aspect of the present invention is a method for producing a thick film resist pattern including a lamination step for producing the thick film photoresist laminate, an exposure step for selectively irradiating the thick film photoresist laminate with active light or radiation, and a developing step for producing a thick film resist pattern following the exposure step.

A fourth aspect of the present invention is a method for producing a connecting terminal, including a step for forming a connection terminal formed from a conductor on a resist-free portion of a thick film resist pattern produced using the method for producing a thick film resist pattern.

### EFFECTS OF THE INVENTION

The present invention provides a positive photoresist composition which can obtain high sensitivity when forming a thick film resist pattern, a thick film photoresist laminate using the same, a method for producing a thick film resist pattern, and a method for producing a connecting terminal.

### BEST MODE FOR CARRYING OUT THE INVENTION

As follows is a detailed specification of the present invention.

In this specification and in the claims, the term “structural unit” refers to a monomer unit which consists of a resin.

In this specification and in the claims, the term “structural unit derived from an acrylate ester” refers to a structural unit that is generated by cleavage of the ethylenic double bond of the acrylate ester.

The term “structural unit derived from an acrylate ester” refers to a structural unit having a hydrogen atom bonded at an α position substituted with other substituent groups such as a halogen atom, an alkyl group, a halogenated alkyl group or the like, a structural unit derived from an acrylate ester having a hydrogen atom bonded at an α position and the like.

In a “structural unit derived from an acrylate ester”, unless stated otherwise, the term “a-position (a-position carbon atom)” refers to the carbon atom to which the carboxyl group is bonded.

Furthermore, unless stated otherwise, an “alkyl group” refers to a straight-chained, cyclic, or branched-chained alkyl group.

<A Compound (A) that Generates Acid on Irradiation with Active Light or Radiation>

The compound (A) that generates acid on irradiation with active light or radiation in the present invention (hereafter referred to as the component (A)) is an acid generator, and there are no particular restrictions on the compound, provided it generates acid, either directly or indirectly, on irradiation.

[1] Specific examples of the component (A) include, an onium salt (A1) having a naphthalene ring at a cation portion [hereafter referred to as the component (A1)].

The cation portion in the component (A1) has at least one naphthalene ring. The term “having a naphthalene ring” refers to have a structure derived from a naphthalene, that is, to have at least two ring structures and keep the aromatic characteristics. This naphthalene ring may have a substituent group such as a straight-chained or branched-chained alkyl group of 1 to 4 carbon atoms, a hydroxyl group and a straight-chained or branched-chained alkoxy group of 1 to 4 carbon atoms.

The structure derived from the naphthalene ring may be a monovalent group (one free valency) or a divalent group (two free valencies), but is preferably a monovalent group (provided that the number of free valencies is counted except for the moiety to be bonded with the above substituent). For example, the number of naphthalene rings is preferably 1 to 3.

The cation portion of the component (A1) preferably has a structure represented by the following general formula (A1):

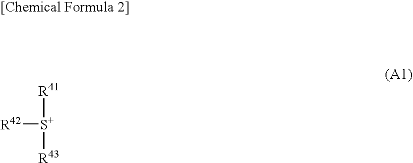

[wherein, at least one of R⁴¹, R⁴² and R⁴³ represents a group represented by the following general formula (A1-0) and the others represent a straight-chained or branched-chained alkyl group having 1 to 4 carbon atoms, a phenyl group which may have a substituent group, a hydroxyl group, or a straight-chained or branched-chained alkoxy group having 1 to 4 carbon atoms; or at least one of R⁴¹, R⁴² and R⁴³ represents a group represented by the following general formula (A1-0) and the other two substituent groups each independently represents a straight-chained or branched-chained alkylene group having 1 to 4 carbon atoms, and ends thereof may be combined to form a ring].

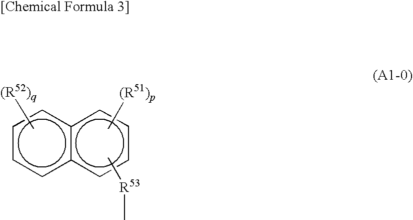

[wherein, R⁵¹ and R⁵² each independently represents a hydroxyl group, a straight-chained or branched-chained alkoxy group having 1 to 4 carbon atoms, or a straight-chained or branched-chained alkyl group having 1 to 4 carbon atoms; R⁵³ represents a single bond or a straight-chained or branched-chained alkylene group having 1 to 4 carbon atoms which may have a substituent group or —CH₂C(═O)— group; and p and q each independently represents an integer of 0 or 1 to 2, and p+q is 3 or less and also may be the same or different with each other when a plurality of R⁵¹ exist, or may be the same or different with each other when a plurality of R⁵² exist.]

At least one of R⁴¹, R⁴² and R⁴³ is a group represented by the above general formula (A1-0). The number of the group represented by the general formula (A1-0) is preferably 1 in view of stability of the compound.

In the formula represented by the general formula (A1-0), R⁵¹ and R⁵² each independently represents a hydroxyl group, a straight-chained or branched-chained alkoxy group having 1 to 4 carbon atoms, or a straight-chained or branched-chained alkyl group having 1 to 4 carbon atoms. These substituents are preferable in view of solubility of the component (A) in the resist composition.

P and q each independently represents an integer of 0 or 1 to 2, and p+q is 3 or less.

R⁵³ is a single bond, or a straight-chained or branched-chained alkylene group having 1 to 4 carbon atoms which may have a substituent, and is preferably a single bond. The single bond means that the number of carbon atoms is 0.

Examples of the substituent, with which the alkylene group is substituted, include an oxygen atom (which combines with carbon atoms constituting the alkylene group to form a carbonyl group in this case) and hydroxyl group.

The others among R⁴¹, R⁴² and R⁴³ represent a straight-chained or branched-chained alkyl group having 1 to 4 carbon atoms, or a phenyl group which may have a substituent.

Examples of the substituent, with which the phenyl group is substituted, include a hydroxyl group, a straight-chained or branched-chained alkoxy group having 1 to 4 carbon atoms, or a straight-chained or branched-chained alkyl group having 1 to 4 carbon atoms.

One of R⁴¹, R⁴² and R⁴³ represents a group represented by the following general formula (A1-0) and the other two substituents each independently represents a straight-chained or branched-chained alkylene group having 1 to 4 carbon atoms, and ends thereof may be combined to form a ring.

In this case, two alkylene groups described above constitute 3- to 9-membered rings, including a sulfur atom. The number of atoms (including the sulfur atom) constituting the ring is preferably from 5 to 6.

Examples of preferable cation portion the component (A1) include those represented by the following chemical formulas (A1-1) and (A1-2), and a structure represented by the chemical formula (A1-2) is particularly preferable.

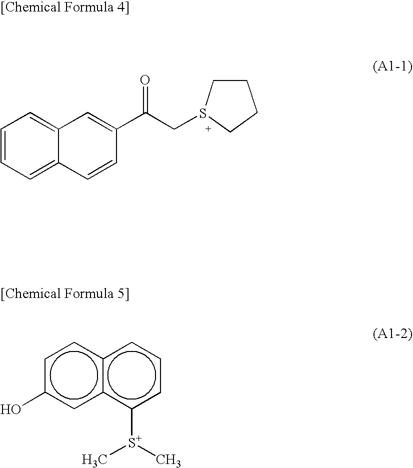

The component (A1) may be either an iodonium salt or a sulfonium salt, but is preferably a sulfonium salt in view of acid generation efficiency.

Therefore, the anion portion of the component (A1) is preferably an anion capable of forming a sulfonium salt.

Particularly preferred is a fluoroalkylsulfonic acid ion or allylsulfonic acid ion, a portion or all of hydrogen atoms being fluorinated.

The alkyl group in the fluoroalkylsulfonic acid ion may be a straight-chained, branched or cyclic alkyl group having 1 to 20 carbon atoms. In view of bulkiness of the acid to be generated and its diffusion length, the number of carbon atoms is from 1 to 10. A branched or cyclic alkyl group is particularly preferable because of the short diffusion length. Specific examples of the alkyl group are a methyl group, an ethyl group, a propyl group, a butyl group and an octyl group because they can be synthesized at a low cost.

Examples of the aryl group in the allylsulfonic acid include aryl groups having 6 to 20 carbon atoms, which may be substituted or unsubstituted with an alkyl group or a halogen atom, such as phenyl group and naphthyl group. An aryl group having 6 to 10 carbon atoms is preferable because it can be synthesized at a low cost. Specific examples of a preferable aryl group include a phenyl group, a toluenesulfonyl group, an ethylphenyl group, a naphthyl group and a methylnaphthyl group.

The fluorination degree is preferably from 10 to 100%, and more preferably from 50 to 100%. A sulfonate in which all hydrogen atoms are substituted with a fluorine atom is preferable because acidity is enhanced. Specific examples thereof include trifluoromethane sulfonate, perfluorobutane sulfonate, perfluorooctane sulfonate and perfluorobenzene sulfonate.

Examples of a preferable anion portion include those represented by the following general formulas (A1-3).

[Chemical Formula 6]

R⁴⁴SO³⁻ (A1-3)

In the general formula (A1-3), examples of R⁴⁴ include structures represented by the following general formulas (A1-4) and (A1-5), and structures represented by the chemical formula (A1-6):

[Chemical Formula 7]

CₗF₂ₗ₊₁ (A1-4)

[wherein, 1 represents an integer of 1 to 4].

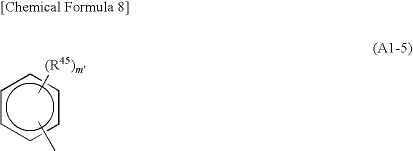

[wherein, R⁴⁵ represents a hydrogen atom, a hydroxyl group, a straight-chained or branched-chained alkyl group having 1 to 4 carbon atoms, or a straight-chained or branched-chained alkoxy group having 1 to 4 carbon atoms, and m′ represents an integer of 1 to 3].

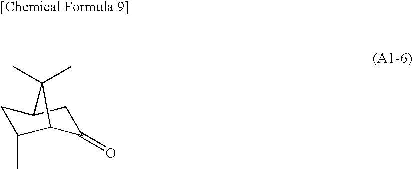

Taking account of safety, trifluoromethanesulfonate and perfluorobutanesulfonate are preferable.

As the anion portion, those having a structure containing nitrogen can also be used.

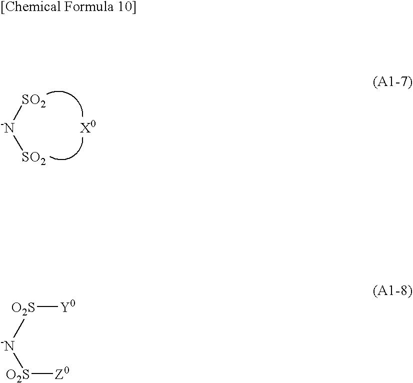

In the formulas (A1-7) and (A1-8), X⁰ represents a straight-chained or branched alkylene group in which at least one hydrogen atom is substituted with a fluorine atom, and the number of carbon atoms of the alkylene group is from 2 to 6, preferably from 3 to 5, and more preferably 3.

Y⁰ and Z⁰ each independently represents a straight-chained or branched alkyl group in which at least one hydrogen atom is substituted with a fluorine atom, and the number of carbon atoms of the alkyl group is from 1 to 10, preferably from 1 to 7, and more preferably from 1 to 3.

The smaller the number of carbon atoms of the alkylene group as for X⁰ and the number of carbon atoms of the alkyl group as for Y⁰ and Z⁰, the better solubility in a resist solvent, and thus it is preferred.

In the alkylene group as for X⁰ and the alkyl group as for Y⁰ and Z⁰, the larger the number of hydrogen atoms substituted with a fluorine atom, the more aciditivity becomes strong, and thus it is preferred. The content of the fluorine atom in the alkylene group or alkyl group, that is, the fluorination degree is preferably from 70 to 100%, and more preferably from 90 to 100%. A perfluoroalkylene group or perfluoroalkyl group in which all hydrogen atoms are substituted with a fluorine atom is most preferred.

Examples of preferable, component (A1) are listed in (A1-9) and (A1-10) below.

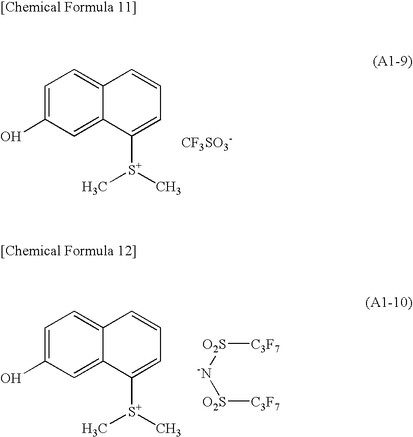

Specific examples of the component which can be used as the component (A) other than the component (A1) are below.

[2] Specific examples include halogen-containing triazine compounds such
as 2,4-bis(trichloromethyl)-6-piperonyl-1,3,5-triazine,
2,4-bis(trichloromethyl)-6-[2-(2-furyl)ethenyl]-s-triazine,
2,4-bis(trichloromethyl)-6-[2-(5-methyl-2-furyl)ethenyl]-s-triazine,
2,4-bis(trichloromethyl)-6-[2-(5-ethyl-2-furyl)ethenyl]-s-triazine,
2,4-bis(trichloromethyl)-6-[2-(5-propyl-2-furyl)ethenyl]-s-triazine,
2,4-bis(trichloromethyl)-6-[2-(3,5-dimethoxyphenyl)ethenyl]-s-triazine,
2,4-bis(trichloromethyl)-6-[2-(3,5-diethoxyphenyl)ethenyl]-s-triazine,
2,4-bis(trichloromethyl)-6-[2-(3,5-dipropoxyphenyl)ethenyl]-s-triazine,
2,4-bis(trichloromethyl)-6-[2-(3-methoxy-5-ethoxyphenyl)ethenyl]-s-triazine,
2,4-bis(trichloromethyl)-6-[2-(3-methoxy-5-propoxyphenyl)ethenyl]-s-triazine,
2,4-bis(trichloromethyl)-6-[2-(3,4-methylenedioxyphenyl)ethenyl]-s-triazine,
2,4-bis(trichloromethyl)-6-(3,4-methylenedioxyphenyl)-s-triazine,
2,4-bis-trichloromethyl-6-(3-bromo-4-methoxy)phenyl-s-triazine,
2,4-bis-trichloromethyl-6-(2-bromo-4-methoxy)phenyl-s-triazine,
2,4-bis-trichloromethyl-6-(2-bromo-4-methoxy)styrylphenyl-s-triazine,
2,4-bis-trichloromethyl-6-(3-bromo-4-methoxy)styrylphenyl-s-triazine,
2-(4-methoxyphenyl)-4,6-bis(trichloromethyl)-1,3,5-triazine,
2-(4-methoxynaphthyl)-4,6-bis(trichloromethyl)-1,3,5-triazine,
2-[2-(2-furyl)ethenyl]-4,6-bis(trichloromethyl)-1,3,5-triazine,
2-[2-(5-methyl-2-furyl)ethenyl]-4,6-bis(trichloromethyl)-1,3,5-triazine,
2-[2-(3,5-dimethoxyphenyl)ethenyl]-4,6-bis(trichloromethyl)-1,3,5-triazine,
2-[2-(3,4-dimethoxyphenyl)ethenyl]-4,6-bis(trichloromethyl)-1,3,5-triazine,
2-(3,4-methylenedioxyphenyl)-4,6-bis(trichloromethyl)-1,3,5-triazine,
tris(1,3-dibromopropyl)-1,3,5-triazine; and tris(2,3-dibromopropyl)-1,3,5-triazine
   represented by a general formula (A2-1) shown below:

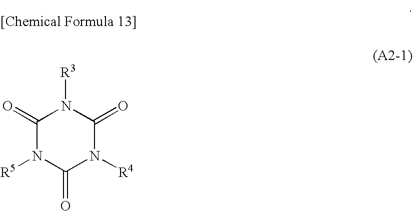

[wherein, R³ to R⁵ may be either the same or different, and each represents a halogenated alkyl group]. The number of carbon atoms in this halogenated alkyl group is preferably 1 to 10.

[3] Other specific examples of the component (A) include an oxime sulfonate-based acid generator such as a-(p-toluenesulfonyloxyimino)-phenylacetonitrile, a-(benzenesulfonyloxyimino)-2,4-dichlorophenylacetonitrile, a-(benzenesulfonyloxyimino)-2,6-dichlorophenylacetonitrile, a-(2-chlorobenzenesulfonyloxyimino)-4-methoxyphenylacetonitrile, a-(ethylsulfonyloxyimino)-1-cyclopentenylacetonitrile, and a compound represented by a general formula (A2-2) shown below:

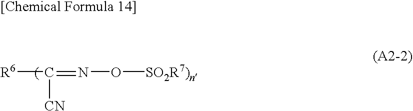

[wherein, R⁶ represents a monovalent to bivalent organic group, R⁷ represents a substituted or unsubstituted saturated hydrocarbon group, unsaturated hydrocarbon group, or aromatic compound group, and n′ represents a natural number within a range from 1 to 3]. The number of carbon atoms in the organic group as R⁶ is preferably 1 to 12.

Specific examples of monovalent to trivalent organic group the R⁶ include an aromatic compound group.

Here, the term “aromatic compound group” refers to a group formed from a compound that shows the characteristic physical and chemical properties of an aromatic compound, and specific examples include aromatic hydrocarbon groups such as a phenyl group or naphthyl group, and heterocyclic groups such as a furyl group or a thienyl group. These groups may also include suitable substituents on the ring, including one or more halogen atoms, alkyl groups, alkoxy groups, or nitro groups.

Specific examples of substituent groups in a saturated hydrocarbon group as R⁷ include a halogen atom. Specific examples of an unsaturated hydrocarbon group as R⁷ include an alkenyl group of 1 to 4 carbon atoms. Furthermore, as the group R⁷, alkyl groups of 1 to 4 carbon atoms are particularly preferred, including a methyl group, an ethyl group, a propyl group, and a butyl group.

Compounds in which R⁶ represents an aromatic compound group, and R⁷ represents a lower alkyl group of 1 to 4 carbon atoms are particularly preferred.

Examples of the acid generators represented by the above general formula (A2-2), in the case where n′=1, include compounds in which R⁶ is a phenyl group, a methylphenyl group or a methoxyphenyl group, and R⁷ is a methyl group, namely, a-(methylsulfonyloxyimino)-1-phenylacetonitrile, a-(methylsulfonyloxyimino-1-(p-methy lphenyl)acetonitrile, and a-(methylsulfonyloxyimino)-1-(p-methoxyphenyl)acetonitrile. In the case where n′= 2, specific examples of the acid generators represented by the above general formula include a compound group (A2-2i) of the add generators represented by the chemical formulas shown below.

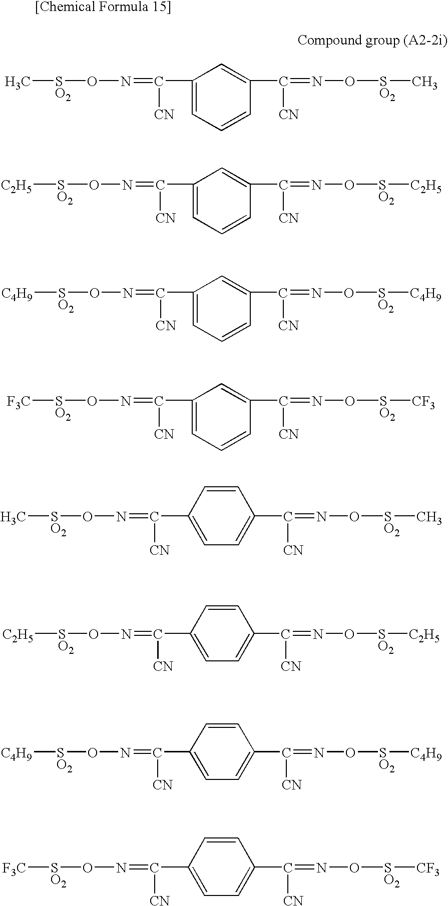

[4] Other specific examples of the component (A) include bissulfonyldiazomethanes such as bis(p-toluenesulfonyl) diazomethane, bis(1,1-dimethylethylsulfonyl) diazomethane, bis(cyclohexylsulfonyl) diazomethane, and bis(2,4-dimethylphenylsulfonyl) diazomethane;

[5] Other specific examples of the component (A) include nitrobenzyl derivatives such as 2-nitrobenzyl p-toluenesulfonate, 2,6-nitrobenzyl p-toluenesulfonate, nitrobenzyl tosylate, dinitrobenzyl tosylate, nitrobenzyl sulfonate, nitrobenzyl carbonate, and dinitrobenzyl carbonate;

[6] Other specific examples of the component (A) include sulfonic acid esters such as pyrogallol trimesylate, pyrogallol tritosylate, benzyl tosylate, benzyl sulfonate, N-methylsulfonyloxysuccinimide, N-trichloromethylsulfonyloxysuccinimide, N-phenylsulfonyloxymaleimide, and N-methylsulfonyloxyphthalimide;

[7] Other specific examples of the component (A) include trifluoromethanesulfonic acid esters such as N-hydroxyphthalimide and N-hydroxynaphthalimide;

[8] Other specific examples of the component (A) include onium salts such as diphenyliodonium hexafluorophosphate, (4-methoxyphenyl)phenyliodonium trifluoromethanesulfonate, bis(p-tert-butylphenyl)iodonium trifluoromethanesulfonate, triphenylsulfonium hexafluorophosphate, (4-methoxyphenyl)diphenylsulfonium trifluoromethanesulfonate, and (p-tert-butylphenyl)diphenylsulfonium trifluoromethanesulfonate;

[9] Other specific examples of the component (A) include benzoin tosylates such as benzoin tosylate and a-methylbenzoin tosylate;

[10] Other specific examples of the component (A) include other diphenyliodonium salts, triphenylsulfonium salts, phenyldiazonium salts, and benzyl carbonate.

Of these compounds in [1] to [10] above, the oxime sulfonate-based acid generators in [3] are preferable. Of these, preferred compounds for the component (A) include compounds containing at least two oxime sulfonate groups represented by the general formula (A2-3) shown below:

R′—SO₂O—N═C(CN)— (A2-3)

(wherein, R′ represents a substituted or unsubstituted alkyl group or aryl group of, for example, 1 to 8 carbon atoms), and of these, compounds represented by the general formula (A2-4) shown below are particularly preferred.

R′—SO₂O—N═C(CN)-A-C(CN)═N—OSO₂—R′ (A2-4)

(wherein, A represents a bivalent, substituted or unsubstituted alkylene group of 1 to 8 carbon atoms, or a bivalent aromatic compound group, and R′ represents a substituted or unsubstituted alkyl group or aryl group of, for example, 1 to 8 carbon atoms).

Here, the term “aromatic compound group” is as defined above for R⁶ above aromatic compound group.

Examples of an alkyl group in R′ include a halogen atom. Examples of a substituent group in an aryl group include one or more of a halogen atom, an alkyl group, an alkoxy group, or a nitro group. Furthermore, examples of a substituent group in an alkylene group of A include a halogen atom.

Moreover, compounds of the above general formula in which A represents a phenylene group and R′ represents, for example, a lower alkyl group of 1 to 4 carbon atoms are particularly desirable.

This component (A) can use either a single compound, or a combination of two or more different compounds.

The blend quantity of the component (A) in the positive photoresist composition is typically within the range of 0.1 to 20 parts by weight, and preferably within the range of 0.1 to 10 parts by weight, per 100 parts by weight of the component (B) and an optionally added component (C) below. By ensuring this quantity is at least 0.1 parts by weight, satisfactory sensitivity can be achieved, and by ensuring the quantity is no more than 20 parts by weight, a favorable solubility is achieved in the solvent, enabling the formation of a homogeneous solution, which tends to improve the storage stability.

<Resin that Displays Increased Alkali Solubility Under the Action of Acid (B)>

A resin that displays increased alkali solubility under the action of acid (B) (hereafter referred to as the component (B)), used in a chemically amplified positive photoresist composition for a thick film according to the present invention, is a structural unit derived from an acrylate ester, wherein the component (B) includes a resin (B1) including a structural unit (b1), in which a hydrogen atom in a carboxy group is substituted with an acid dissociable represented be the general formula above (I), dissolution inhibiting group.

### <Resin (B1)>

[Structural Unit (b1)]

A structural unit (b1) is a structural unit derived from an acrylate ester, wherein the structural unit (b1) has a structure in which an acetal group (an alkoxyalkyl group)-type acid dissociable, dissolution inhibiting group [—C(R¹R²)—O—(CH₂)ₙ—Y] is bonded at an oxygen atom on the terminal of its carbonyloxy group (—C(O)—O—). Therefore, a linkage between the acid dissociable, dissolution inhibiting group, and the oxygen atom on the terminal is dissociated under action of an acid.

Since the component (B) includes the resin (B1) having the structural unit (b1) which has the acid dissociable, dissolution inhibiting group, the component (B) is configured to dissociate its acid dissociable, dissolution inhibiting group under action of acid generated by the component (A) on exposure. By virtue of this, the component (B) which is insoluble in alkali prior to exposure can increase its alkali solubility as the entire component (B). In forming a resist pattern, when the resist of the present invention is subject to selective exposure or post exposure baking (PEB) in addition to the exposure, an exposed area changes so as to have alkali solubility, while the alkali insolubility of an unexposed area is maintained as it is. Thus, by subjecting the resist to alkali development, a positive resist pattern can be formed.

In the general formula (I), R¹ and R² each represents, independently, a hydrogen atom or an lower alkyl group of 1 to 5 carbon atoms. Specific examples of the lower alkyl group include a methyl group, an ethyl group, a propyl group, an isopropyl group, an n-butyl group, an isobutyl group, a tert-butyl group, a pentyl group, an isopentyl group, and a neopentyl group.

At least one of R¹ and R² is a hydrogen atom, and more preferably both of them are hydrogen atoms.

In the general formula (I), n represents either 0 or an integer from 1 to 3. Preferably, n is 0 or 1, more preferably 0.

In the general formula (I), Y represents an aliphatic cyclic group or an alkyl group. The aliphatic cyclic group may or may not have a substituent group on the cyclic skeleton. Y is preferably an aliphatic cyclic group which may have a substituent group.

In the present claims and specification, the term “aliphatic” refers to a concept relative to aromatic, and is defined as a group, a compound, etc. that does not have aromaticity. The “aliphatic cyclic group” refers to a monocyclic group or a polycyclic group that does not have aromaticity.

The structure of the basic ring from which the substituent of the present “aliphatic cyclic group” is excluded is not limited to the group consisting of carbon and hydrogen (a hydrocarbon group), but a hydrocarbon group is preferred. The hydrocarbon group may be saturated or unsaturated, but it is usually preferably saturated. The “aliphatic cyclic group” is preferably a polycyclic group.

Specific examples of the aliphatic cyclic group include a group in which at least one hydrogen atom has been removed from a monocycloalkane, and a polycycloalkane such as bicycloalkane, tricycloalkane, and tetracycloalkane.

More specific examples thereof include a group in which at least one hydrogen atom has been removed from a monocycloalkane such as cyclopentane and cyclohexane, and from a polycycloalkane such as adamantane, norbornane, isobornane, tricyclodecane, and tetracyclododecane.

Y is preferably a group in which at least one hydrogen atom has been removed from adamantane (which may further include a substituent group).

When the aliphatic cyclic group as Y has a substituent group on the cyclic skeleton, examples of the substituent group include a polar group such as a hydroxyl group, a carboxy group, a cyano group and an oxygen atom (═O), and a straight-chained or branched-chained lower alkyl group of 1 to 4 carbon atoms. When the aliphatic cyclic group has the substituent group on the cyclic skeleton, the substituent group preferably has the polar group and/or the lower alkyl group. Examples of the polar group, an oxygen atom (═O) is particularly preferred. When the aliphatic cyclic group as Y has a substituent group on the cyclic skeleton, the number of substitution is preferably 1 to 3.

An alkyl group as Y is preferably a straight-chained and branched-chained alkyl group of 1 to 20 carbon atoms, more preferably of 6 to 15 carbon atoms.

When Y is an alkyl group, specific examples of an alkoxyalkyl group (chained) represented by the general formula (I) include a 1-methoxyethyl group, a 1-ethoxyethyl group, a 1-n-propoxyethyl group, a 1-isopropoxyethyl group, a 1-n-butoxyethyl group, a 1-iso-butoxyethyl group, a 1-tert-butoxyethyl group, a 1-methoxypropyl group, a 1-methoxy-1-methyl-ethyl group and a 1-ethoxy-1-methyl-ethyl group. Furthermore, the alkyl group as Y is preferably long-chained for plating resistance.

Specific examples of the structural unit (b1), include a structural unit represented by the general formula (b1-01) below and a structural unit represented by the general formula (b1-02) below:

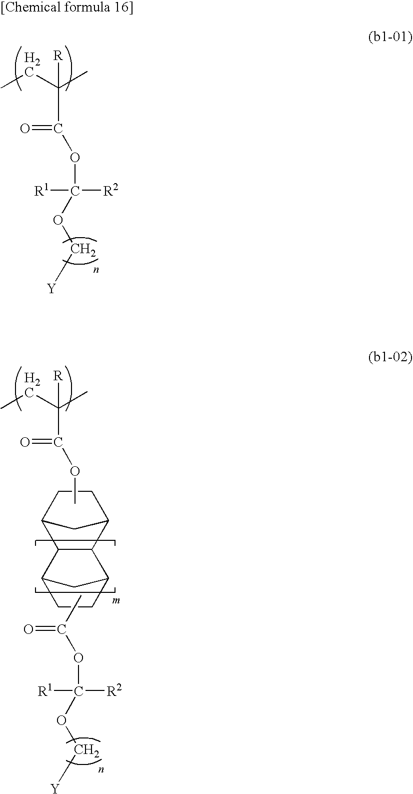

[wherein, Y represents an aliphatic cyclic group which may have a substituent group or an alkyl group; n represents either 0 or an integer from 1 to 3; m represents 0 or 1; R each represents, independently, a hydrogen atom, a lower alkyl group of 1 to 5 carbon atoms, a fluorine atom or a fluorinated lower alkyl group of 1 to 5 carbon atoms; R¹ and R² each represents, independently, a hydrogen atom or an lower alkyl group of 1 to 5 carbon atoms].

In the general formulas (b1-01) and (b1-02), R represents a hydrogen atom, a lower alkyl group of 1 to 5 carbon atoms, a fluorine atom or a fluorinated lower alkyl group of 1 to 5 carbon atoms.

A fluorinated lower alkyl group is a group in which either a portion of, or all of, the hydrogen atoms of an alkyl group have been substituted with fluorine atoms and groups in which all of the hydrogen atoms have been fluorinated are preferred.

Specific examples of a lower alkyl group as R include a methyl group, an ethyl group, a propyl group, an isopropyl group, a n-butyl group, an isobutyl group, a tert-butyl group, a pentyl group, an isopentyl group, and a neopentyl group. From an industrial viewpoint, R is preferably a methyl group.

The fluorinated lower alkyl group of 1 to 5 carbon atoms is preferably a trifluoromethyl group, a hexafluoroethyl group, a heptafluoropropyl group, or a nonafluorobutyl group, more preferably a trifluoromethyl group.

Y, n, R¹ and R² in the general formula (b1-01) and (b1-02) are each as defined above for Y, n, R¹ and R² in the general formula (I).

Examples of the structural unit represented by the general formula (b1-01) above are below.

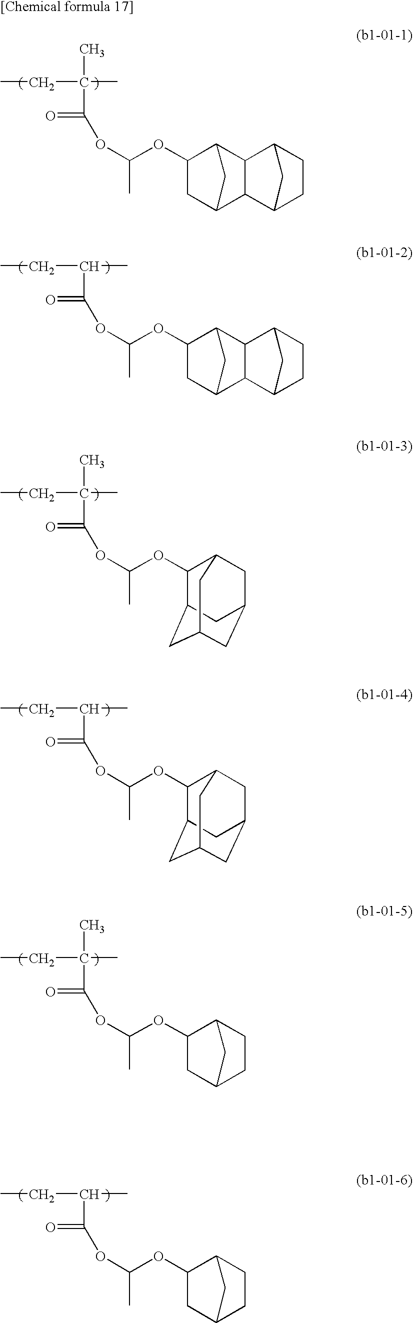

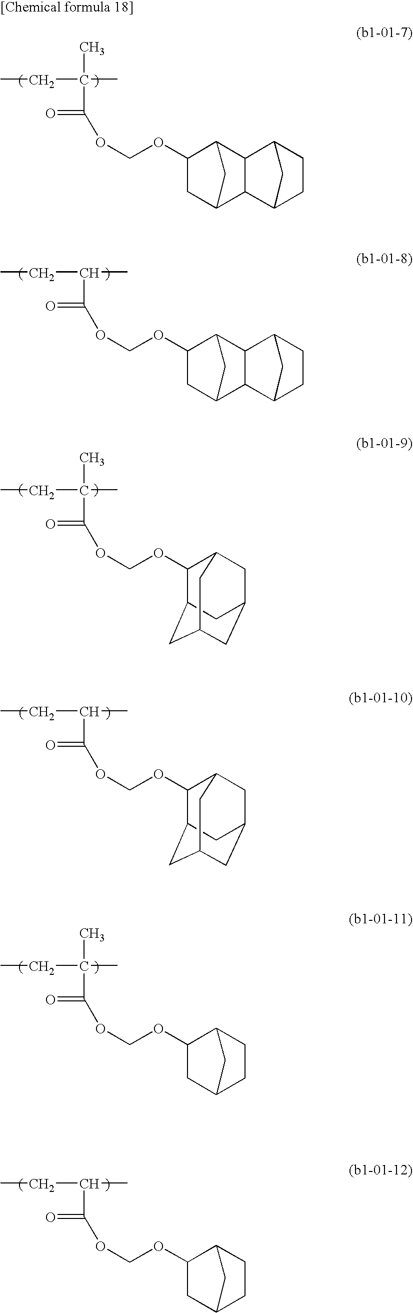

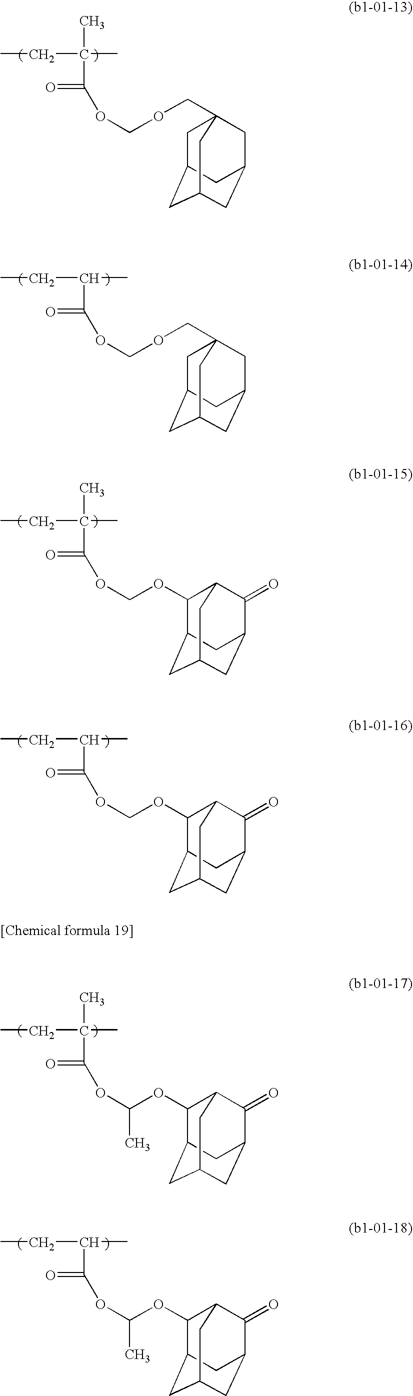

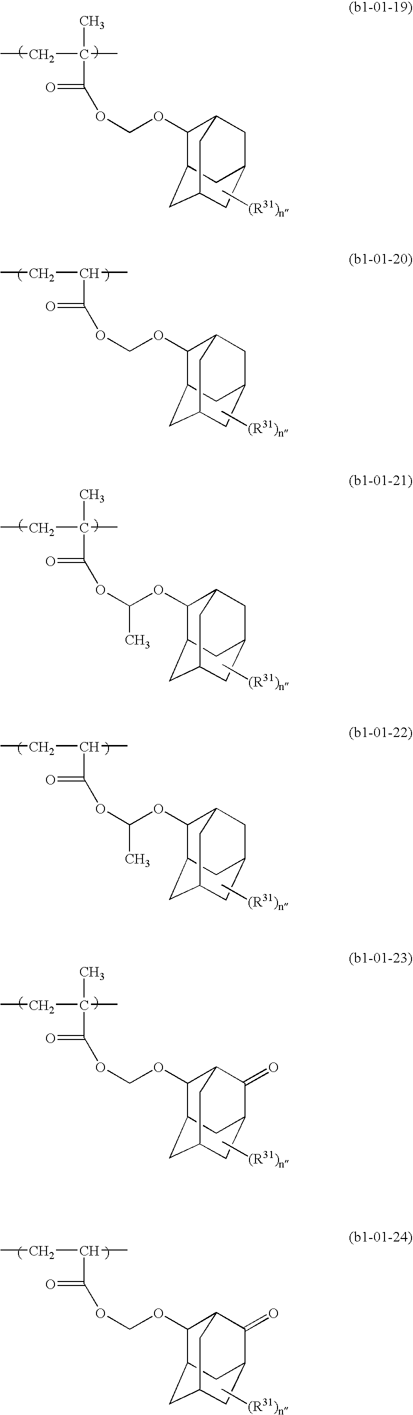

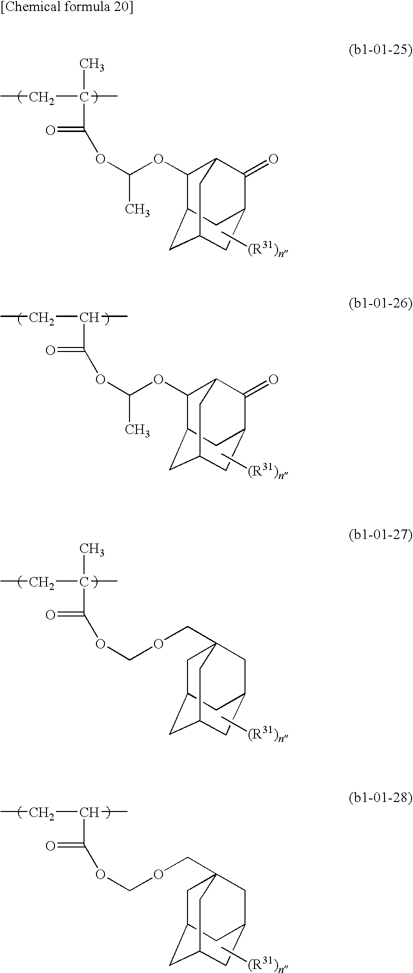

In formulas (b1-01-17)-(b1-01-28), R³¹ represents a straight-chained or branched-chained alkyl group, a hydroxyl group or a CN group, n″ represents an integer from 1 to 3.

Examples of the structural unit represented by the general formula (b1-02) above are below.

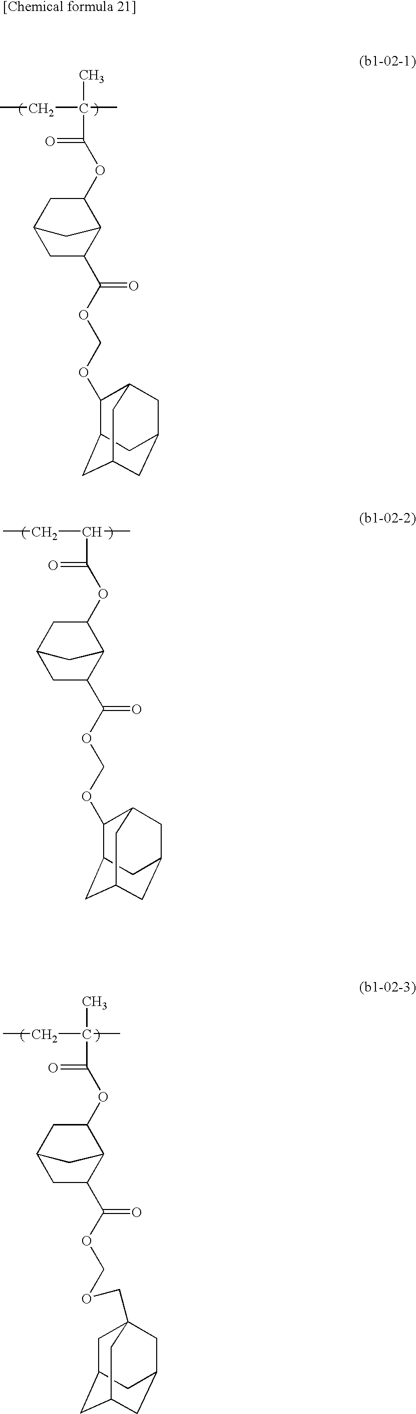

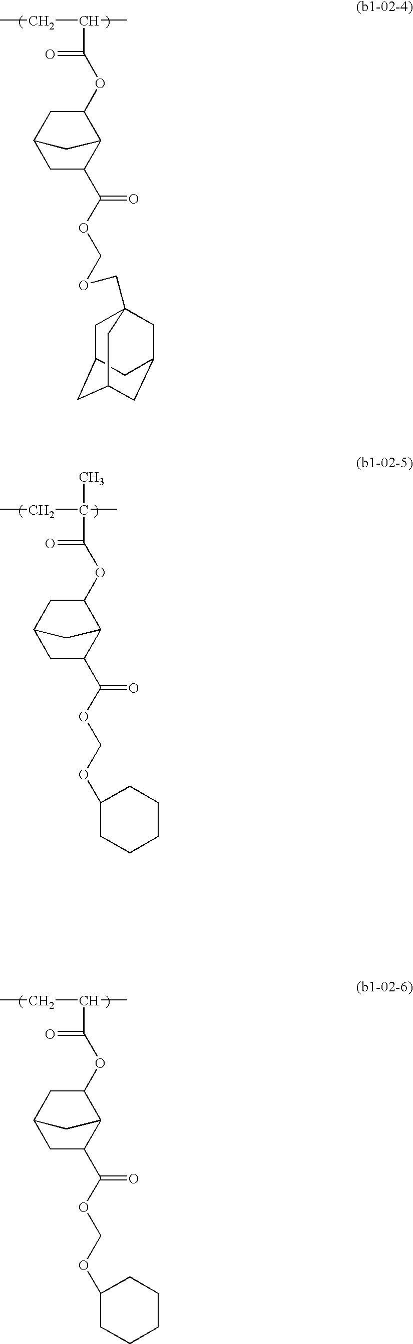

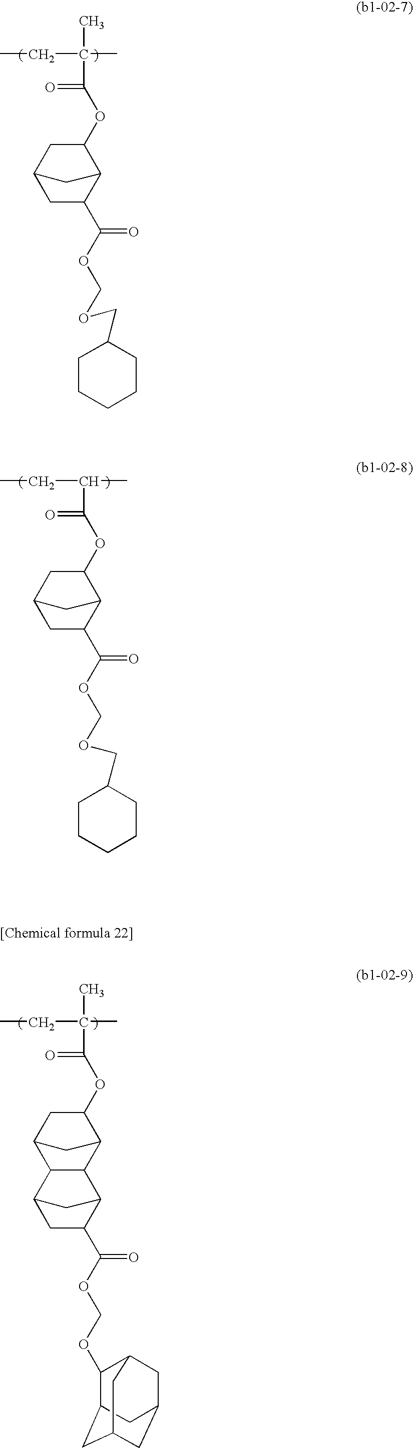

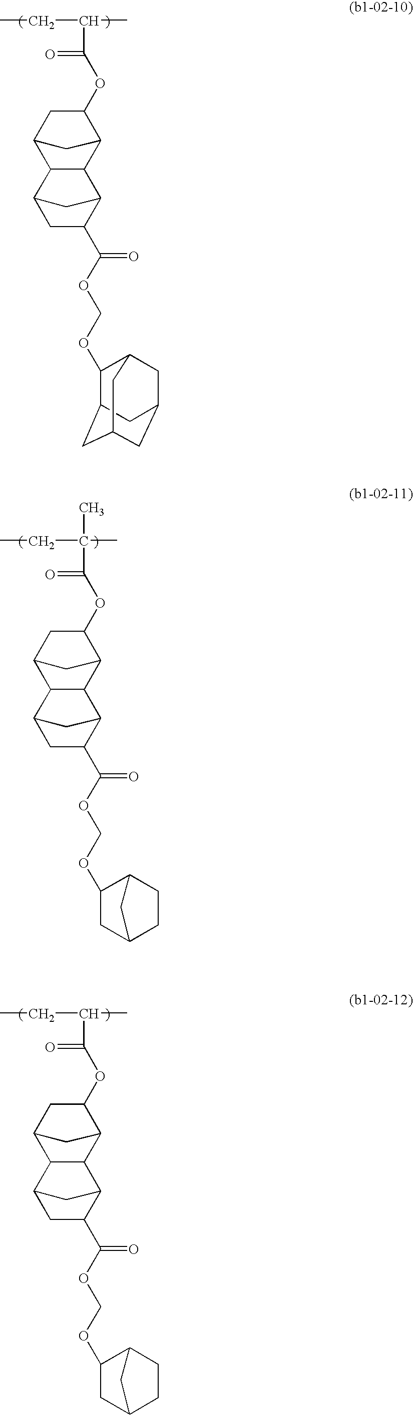

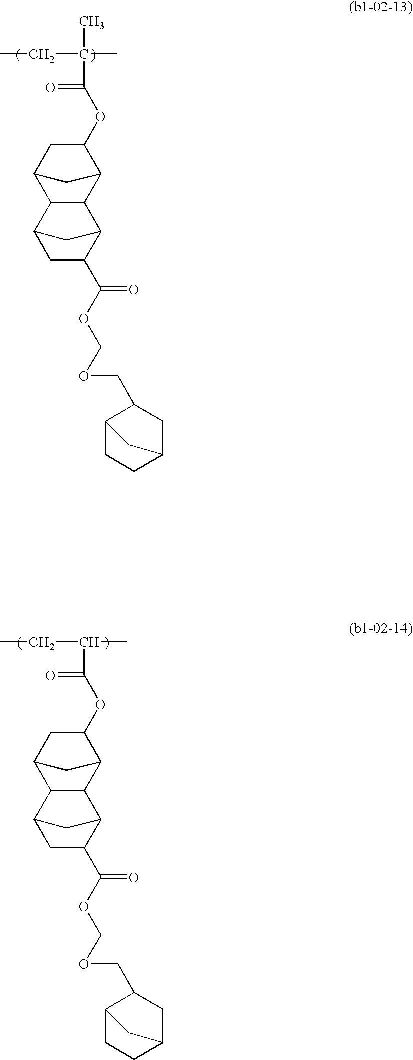

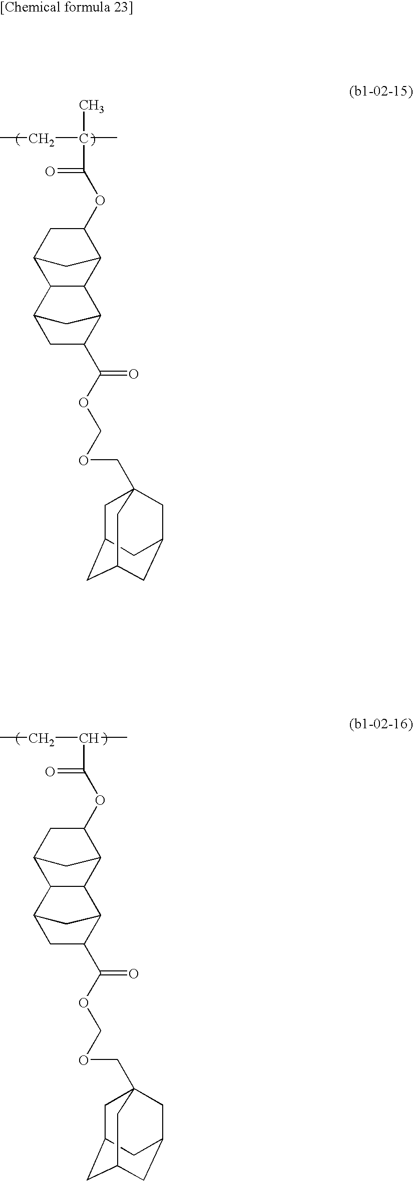

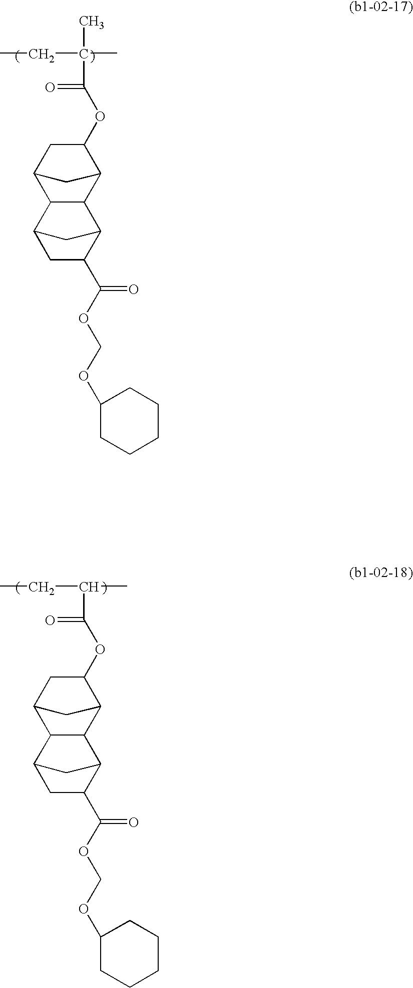

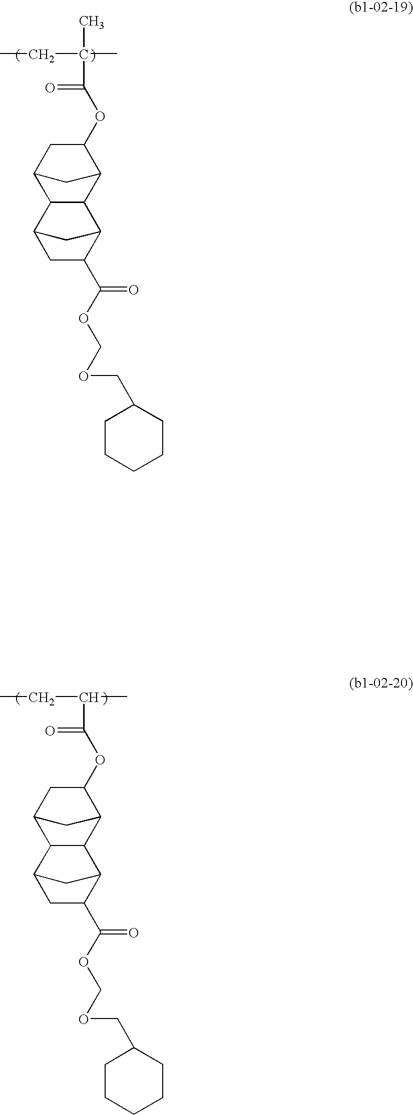

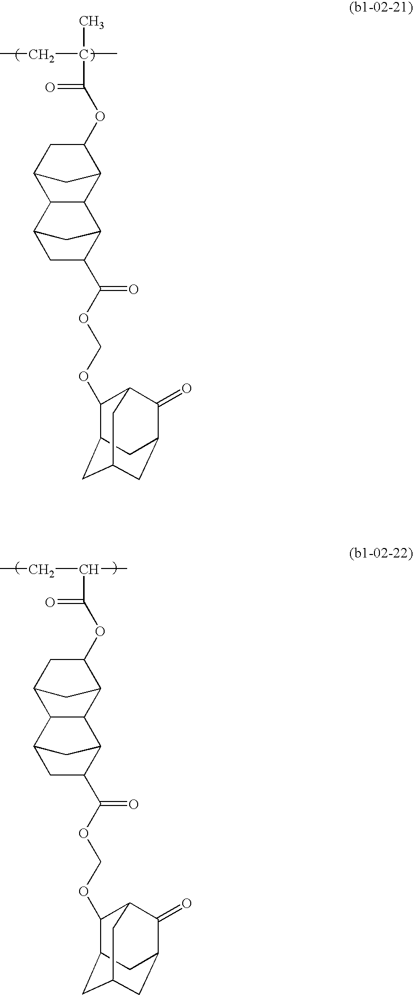

The structural unit (b1) may include either one, or two or more selected from the group consisting of the structural unit represented by the general formula (b1-01) and the structural unit represented by the general formula (b1-02).

The proportion of the structural unit (b1) in the resin (B1) is preferably 10 to 80% by mole, more preferably 20 to 70% by mole, and still more preferably 25 to 60% by mole, based on the total amount of all the structural units that constitute the resin (B1). By ensuring that this proportion is at least as large as the lower limit of the above range, a very fine pattern can be obtained when the resin (B1) is used to form a resist composition, whereas ensuring that the proportion is no greater than the upper limit enables a more favorable balance to be achieved with the other structural units.

[Structural Unit (b2)]

Furthermore, the resin (B1) is preferably a resin consisting of a copolymer including a structural unit (b2) derived from a polymerizable compound containing an ether linkage in addition to the structural unit (b1). By incorporating the component (b2), the adhesion with the substrate during development can be improved, and a more favorable plating solution resistance is achieved.

The structural unit (b2) is a structural unit derived from a polymerizable compound containing an ether linkage. The examples of the polymerizable compound containing an ether linkage include 2-methoxyethyl (meth)acrylate, 2-ethoxyethyl (meth)acrylate, methoxytriethylene glycol (meth)acrylate, 3-methoxybutyl (meth)acrylate, ethylcarbitol (meth)acrylate, phenoxypolyethylene glycol (meth)acrylate, methoxypolypropylene glycol (meth)acrylate, and tetrahydrofurfuryl (meth)acrylate. Of these, 2-methoxyethyl (meth)acrylate, 2-ethoxyethyl (meth)acrylate, and methoxytriethylene glycol (meth)acrylate are preferred. These compounds can be used either singularly, or in combinations of two or more different compounds.

In the present specification, the term “(meth)acrylate” represents either or both of a methacrylate and an acrylate. The term “(meth)acrylic acid” represents either or both of a methacrylic acid and an acrylic acid.

When the resin (B1) includes the structural unit (b2), the proportion of the structural unit (b2) in the resin (B1) is preferably 5 to 80% by mole, more preferably 10 to 60% by mole, and still more preferably 10 to 50% by mole, based on the total amount of all the structural units that constitute the resin (B1). By ensuring that the proportion is no greater than the upper limit enables inhibition of the decrease of the residual film ratio, whereas ensuring that this proportion is at least as large as the lower limit of the above range, the adhesion with the substrate during development can be improved, and a more favorable plating solution resistance is achieved.

[Structural Unit (b3)]

The resin (B1) may further include a structural unit (b3) represented by the general formula (b3-0) below within the range that does not interfere with the effects of the present invention.

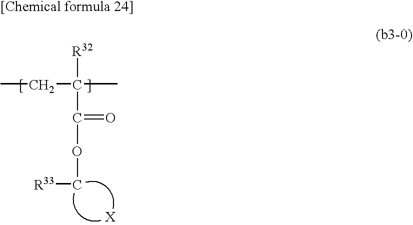

[wherein, R³² represents a hydrogen atom or a methyl group, R³³ represents a lower alkyl group, and X represents a group which, in combination with the carbon atom bonded thereto, forms a hydrocarbon ring of 5 to 20 carbon atoms]

The lower alkyl group represented by R³³ may be either a straight-chained group or a branched-chained group, and suitable examples include an alkyl group of 1 to 5 carbon atoms such as a methyl group, an ethyl group, a n-propyl group, an isopropyl group, a n-butyl group, an isobutyl group, a sec-butyl group, a tert-butyl group, and any of the various pentyl groups. Of these, from the viewpoints of achieving a high level of contrast, and favorable resolution and depth of focus and the like, a lower alkyl group of 2 to 4 carbon atoms is particularly desirable.

Furthermore, X represents a group which, in combination with the carbon atom bonded thereto, forms a monocyclic or polycyclic hydrocarbon ring system of 5 to 20 carbon atoms.

Examples of monocyclic hydrocarbon rings include cyclopentane, cyclohexane, cycloheptane, and cyclooctane.

Examples of polycyclic hydrocarbon ring systems include bicyclic hydrocarbon ring systems, tricyclic hydrocarbon ring systems, and tetracyclic hydrocarbon ring systems. Specific examples include polycyclic hydrocarbon ring systems such as adamantane, norbornane, isobornane, tricyclodecane, and tetracyclododecane.

Of these, particularly preferred forms of X, which represent a group which, in combination with the carbon atom bonded thereto, forms a monocyclic or polycyclic hydrocarbon ring system of 5 to 20 carbon atoms, are a cyclohexane ring and an adamantane ring system.

These specific examples of the structural unit (b3) include structural units represented by the general formulas (b3-1), (b3-2) and (b3-3) below.

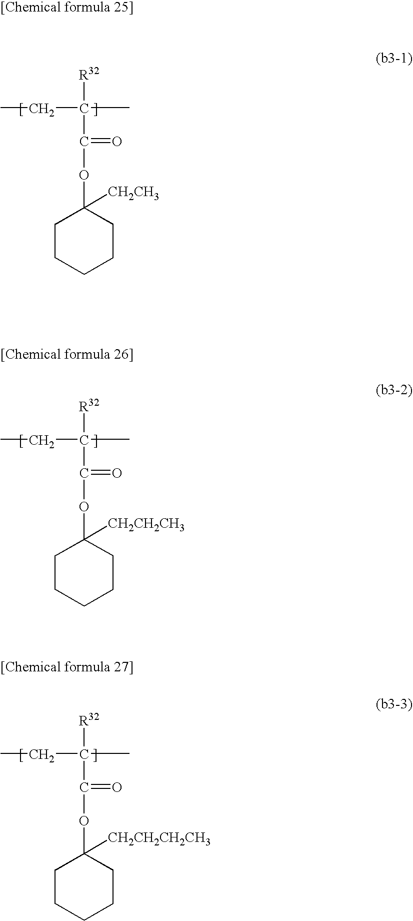

The structural unit (b3) may either include a single structural unit represented by the above general formula (b3-0), or include two or more structural units with different structures.

When the resin (B1) includes the structural unit (b3), the proportion of the structural unit (b3) in the resin (B1) is preferably 0 to 50% by mole, based on the total amount of all the structural units that constitute the resin (B1). By ensuring that the proportion of the structural unit (b3) is no greater than the upper limit enables control of the diffusion length of the acid.

### [Other Polymerizable Compounds]

Furthermore, the resin (B1) may include other polymerizable compounds for the purposes of controlling certain physical and chemical properties. Here, the term “other polymerizable compounds” means polymerizable compounds as structural units other than the structural unit (b1), the structural unit (b2) and the structural unit (b3).

Such polymerizable compounds include known radical polymerizable compounds and anionic polymerizable compounds.

Specific examples include radical polymerizable compounds, including monocarboxylic acids such as acrylic acid, methacrylic acid, and crotonic acid, dicarboxylic acids such as maleic acid, fumaric acid, and itaconic acid, methacrylic acid derivatives containing both a carboxyl group and an ester linkage such as 2-methacryloyloxyethylsuccinic acid, 2-methacryloyloxyethylmaleic acid, 2-methacryloyloxyethylphthalic acid, and 2-methacryloyloxyethylhexahydrophthalic acid; alkyl (meth)acrylates such as methyl (meth)acrylate, ethyl (meth)acrylate, and butyl (meth)acrylate; hydroxyalkyl (meth)acrylates such as 2-hydroxyethyl (meth)acrylate and 2-hydroxypropyl (meth)acrylate; aryl (meth)acrylates such as phenyl (meth)acrylate and benzyl (meth)acrylate; diesters of dicarboxylic acids such as diethyl maleate and dibutyl fumarate; vinyl group-containing aromatic compounds such as styrene, a-methylstyrene, chlorostyrene, chloromethylstyrene, vinyltoluene, hydroxystyrene, a-methylhydroxystyrene, and a-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; and amide bond-containing polymerizable compounds such as acrylamide and methacrylamide.

The polystyrene equivalent weight average molecular weight (hereafter referred to as the weight average molecular weight) of the resin (B1) is preferably 10,000 to 500,000, and even more preferably 20,000 to 400,000. If the weight average molecular weight is less than the upper limit, then the decrease of strippability is controlled. If the weight average molecular weight exceeds the lower limit, then the resist film can attain sufficient strength, decreasing the danger of blistering or cracking of the resist profile during plating.

The degree of dispersion of the resin (B1) is preferably 1.05 or more. The degree of dispersion refers to the ratio of weight average molecular weight/number average molecular weight. Since the degree of dispersion is 1.05 or more, the stress resistance to plating is decreased and the tendency of the metal layer to swell is controlled.

### <Resin(B2)>

Although the component (B) may be 100% of the resin (B1), the component (B) may be a mixed resin including the resin (B1) and a resin (B2) which consists of a copolymer having a structural unit (b4) represented by the general formula (b4-1) below.

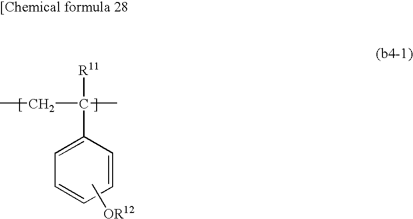

[wherein, R¹¹ represents a hydrogen atom or a methyl group; R¹² represents an acid-labile group].

As this acid-labile group of R¹², a variety of different groups may be selected, although groups represented by the formulas (b4-2) and (b4-3) shown below, straight-chained, branched-chained, or cyclic alkyl groups of 1 to 6 carbon atoms, tetrahydropyranyl groups, tetrafuranyl groups, and trialkylsilyl groups are preferred.

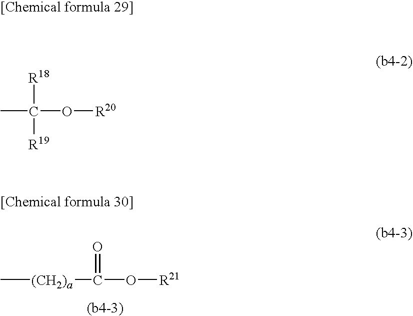

[wherein, in the above formulas, R¹⁸ and R¹⁹ each represent, independently, a hydrogen atom, or a straight-chained or branched-chained alkyl group of 1 to 6 carbon atoms; R²⁰ represents a straight-chained, branched-chained, or cyclic alkyl group of 1 to 10 carbon atoms; R²¹ represents a straight-chained, branched, or cyclic alkyl group of 1 to 6 carbon atoms; and a represents either 0 or 1.]

Examples of the straight-chained or branched alkyl groups include methyl groups, ethyl groups, propyl groups, isopropyl groups, n-butyl groups, iso-butyl groups, and tert-butyl groups, whereas an example of the cyclic alkyl group is a cyclohexyl group.

Examples of the acid-labile group represented by the general formula (b4-2) above include the examples of the alkoxyalkyl group (chained) in the case where the Y is n alkyl group in the general formula (I).

Examples of the acid-labile group represented by the general formula (b4-3) above include a tert-butoxycarbonyl group and a tert-butoxycarbonylmethyl group.

Furthermore, examples of the aforementioned trialkylsilyl group include groups in which the number of carbon atoms of each of the alkyl groups, for example a trimethylsilyl group or a tri-tert-butyldimethylsilyl group, is 1 to 6.

The structural unit (b4) may either contain a single structural unit represented by the above general formula (b4-1), or contain two or more structural units with different structures.

The proportion of the structural unit (b4) in the resin (B2) is preferably 5 to 95% by weight, more preferably 10 to 90% by weight, based on the total amount of all the structural units that constitute the resin (B2). By ensuring that the proportion is no greater than 95% by weight enables to improve the sensitivity, whereas ensuring that this proportion is at least as large as 5% by weight enables inhibition of the decrease of residual film ratio.

Furthermore, the resin (B2) may include a structural unit derived from other polymerizable compounds for the purposes of controlling certain physical and chemical properties. Here, the term “a structural unit derived from other polymerizable compounds” means a structural unit derived from the polymerizable compounds other than the structural unit (b4). Examples of the structural unit derived from the polymerizable compounds include the examples the “structural unit derived from other polymerizable compounds” which may be included in the resin (B1).

### <Alkali-Soluble Resin (C)>

A positive photoresist composition in the present invention preferably includes an alkali-soluble resin (C) (hereafter referred to as the component (C)),

As this component (C), resins selected from amongst known resins commonly used as alkali-soluble resins in conventional chemically amplified photoresists can be used.

Of such resins, those containing at least one resin selected from a group consisting of (c1) novolak resins, (c2) copolymers containing a hydroxystyrene structural unit and a styrene structural unit, (c3) acrylic resins, and (c4) vinyl resins are preferred, and resins comprising a novolak resin (c1) and/or a copolymer (c2) containing a hydroxystyrene structural unit and a styrene structural unit are particularly preferred. The reason for this preference is that such resins facilitate better control of the coatability and the developing rate.

[Novolak Resin (c1)]

The novolak resin of the component (c1) is typically obtained by an addition condensation of an aromatic compound with a phenolic hydroxyl group (hereafter, simply referred to as a phenol) and an aldehyde, in the presence of an acid catalyst.

Examples of the phenol used include phenol, o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethylphenol, 3,4,5-trimethylphenol, p-phenylphenol, resorcinol, hydroquinone, hydroquinone monomethyl ether, pyrogallol, fluoroglucinol, hydroxydiphenyl, bisphenol A, gallic acid, gallic esters, a-naphthol, and β-naphthol.

Furthermore, examples of the aldehyde include formaldehyde, furfural, benzaldehyde, nitrobenzaldehyde, and acetaldehyde.

There are no particular restrictions on the catalyst used in the addition condensation, and suitable acid catalysts include hydrochloric acid, nitric acid, sulfuric acid, formic acid, oxalic acid, and acetic acid.

Novolak resins that use solely m-cresol as the phenol display particularly favorable developing profiles, and are consequently preferred.

[Copolymer Containing a Hydroxystyrene Structural Unit and a Styrene Structural Unit (c2)]

The component (c2) used in the present invention is a copolymer that contains at least a hydroxystyrene structural unit and a styrene structural unit. This includes copolymers having only hydroxystyrene structural units and styrene structural units, as well as copolymers having hydroxystyrene structural units, styrene structural units, and other, different structural units.

Examples of the hydroxystyrene structural unit include hydroxystyrene structural units derived from hydroxystyrenes such as p-hydroxystyrene, or from a-alkylhydroxystyrenes such as a-methylhydroxystyrene and a-ethylhydroxystyrene.

Examples of the styrene structural unit include structural units derived from styrene, chlorostyrene, chloromethylstyrene, vinyltoluene, and a-methylstyrene.

[Acrylic Resin (c3)]

There are no particular restrictions on the acrylic resin of the component (c3), provided it is an alkali-soluble acrylic resin, although acrylic resins including a structural unit derived from a polymerizable compound containing an ether linkage, and a structural unit derived from a polymerizable compound containing a carboxyl group are particularly preferred.

Examples of polymerizable compounds containing an ether linkage include (meth)acrylic acid derivatives containing both an ether linkage and an ester linkage such as 2-methoxyethyl (meth)acrylate, methoxytriethylene glycol (meth)acrylate, 3-methoxybutyl (meth)acrylate, ethylcarbitol (meth)acrylate, phenoxypolyethylene glycol (meth)acrylate, methoxypolypropylene glycol (meth)acrylate, and tetrahydrofurfuryl (meth)acrylate, and of these, 2-methoxyethyl (meth)acrylate and methoxytriethylene glycol (meth)acrylate are preferred. These compounds can be used either singularly, or in combinations of two or more different compounds.

Examples of polymerizable compounds containing a carboxyl group include monocarboxylic acids such as acrylic acid, methacrylic acid, and crotonic acid, dicarboxylic acids such as maleic acid, fumaric acid, and itaconic acid, and compounds containing both a carboxyl group and an ester linkage such as 2-methacryloyloxyethylsuccinic acid, 2-methacryloyloxyethylmaleic acid, 2-methacryloyloxyethylphthalic acid, and 2-methacryloyloxyethylhexahydrophthalic add. Of these, acrylic acid and methacrylic acid are preferred. These compounds can be used either singularly, or in combinations of two or more different compounds.

[Vinyl Resin (c4)]

The vinyl resin of the component (c4) is a poly(vinyl low alkyl ether), and includes a (co)polymer produced by polymerizing either a single vinyl low alkyl ether represented by a general formula (C1) shown below, or a mixture of two or more such ethers.

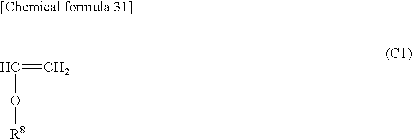

[wherein, R⁸ represents a straight-chained or branched-chained alkyl group of 1 to 5 carbon atoms].

In the general formula (C1), examples of the straight-chained or branched alkyl group of 1 to 5 carbon atoms include a methyl group, an ethyl group, a n-propyl group, an i-propyl group, a n-butyl group, an i-butyl group, a n-pentyl group, and an i-pentyl group. Of these alkyl groups, a methyl group, ethyl group, or i-butyl group is preferred, and a methyl group is particularly desirable. In the present invention, poly(vinyl methyl ether) is a particularly preferred poly(vinyl low alkyl ether).

The blend quantity of the component (C) is typically within a range from 5 to 95 parts by weight, and preferably from 10 to 90 parts by weight, per 100 parts by weight of the component (B), and the component (C). By ensuring that this blend, quantity is at least as large as 5 parts by weight of the above range, cracking resistance can be improved, whereas ensuring the blend quantity is no more than 95 parts by weight tends to prevent thickness loss during development.

### < Acid Diffusion Control Agent (D)>

In the positive photoresist composition according to the present invention, an acid diffusion control agent (D) (hereafter referred to as the component (D)) is preferably added to improve the resist pattern shape, and the post exposure stability of the latent image formed by the pattern-wise exposure of the resist layer.

As the component (D), any of the known compounds typically used as acid diffusion control agents in conventional chemically amplified resists can be selected and used. Incorporating a nitrogen-containing compound (d1) within the component (D) is particularly preferred, and where necessary, (d2) an organic carboxylic acid, a phosphorus oxo acid compound, or a derivative thereof can also be included.

[Nitrogen-Containing Compound (d1)]

Examples of the nitrogen-containing compound of the component (d1) include trimethylamine, diethylamine, triethylamine, di-n-propylamine, tri-n-propylamine, tribenzylamine, diethanolamine, triethanolamine, n-hexylamine, n-heptylamine, n-octylamine, n-nonylamine, ethylenediamine, N,N,N′,N′-tetramethylethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, formamide, N-methylformamide, N-dimethylformamide, acetamide, N-methylacetamide, N,N-dimethylacetamide, propionamide, benzamide, pyrrolidone, N-methylpyrrolidone, methylurea, 1,1-dimethylurea, 1,3-dimethylurea, 1,1,3,3-tetramethylurea, 1,3-diphenylurea, imidazole, benzimidazole, 4-methylimidazole, 8-oxyquinoline, acridine, purine, pyrrolidine, piperidine, 2,4,6tri(2-pyridyl)-s-triazine, morpholine, 4-methylmorpholine, piperazine, 1,4-dimethylpiperazine, and 1,4-diazabicyclo[2.2.2]octane.

Of these, alkanolamines such as triethanolamine are particularly preferred.

These compounds can be used either singularly, or, in a combination of two or more different compounds.

The component (d1) is typically used in quantities within a range from 0 to 5% by weight, and preferably from 0 to 3% by weight, relative to a value of 100% by weight for the combination of the component (B) and the component (C).

[Organic Carboxylic Acid, or a Phosphorus oxo Acid or Derivative Thereof (d2)]

As the organic carboxylic acid, adds such as malonic acid, citric acid, malic acid, succinic acid, benzoic acid, and salicylic acid are ideal, and salicylic acid is particularly desirable.

Examples of the phosphorus oxo acid compound or derivative thereof include phosphoric acid or derivatives thereof such as esters, including phosphoric acid, di-n-butyl phosphate, and diphenyl phosphate; phosphonic acid or derivatives thereof such as esters, including phosphonic acid, dimethyl phosphonate, di-n-butyl phosphonate, phenylphosphonic acid, diphenyl phosphonate, and dibenzyl phosphonate; and phosphinic acid or derivatives thereof such as esters, including phosphinic acid and phenylphosphinic acid. Of these, phosphonic acid is particularly desirable.

These compounds can be used either singularly, or in a combination of two or more different compounds.

The component (d2) is typically used in quantities within a range from 0 to 5% by weight, and preferably from 0 to 3% by weight, relative to a value of 100% by weight for a combination of the component (B) and the component (C).

Furthermore, the component (d2) is preferably used in the same quantity as the component (d1). The reason for this requirement is that the component (d2) and the component (d1) are stabilized through the formation of a mutual salt.

### <Other Components>

Other conventional miscible additives can also be added to a chemically amplified positive photoresist composition for thick film of the present invention according to need, provided such addition does not impair the intrinsic characteristics of the present invention, and examples of such miscible additives include additive resins for improving the properties of the resist film, plasticizers, adhesion assistants, stabilizers, colorants, and surfactants.

### <Organic Solvent>

In addition, the positive photoresist composition in the present invention may also include a suitable quantity of an organic solvent for the purposes of regulating the composition viscosity.

Specific examples of this organic solvent include ketones such as acetone, methyl ethyl ketone, cyclohexanone, methyl isoamyl ketone and 2-heptanone; polyhydric alcohols and derivatives thereof such as ethylene glycol, ethylene glycol monoacetate, diethylene glycol, diethylene glycol monoacetate, propylene glycol, propylene glycol monoacetate, dipropylene glycol, or the monomethyl ether, monoethyl ether, monopropyl ether, monobutyl ether or monophenyl ether of dipropylene glycol monoacetate; cyclic ethers such as dioxane; and esters such as methyl lactate, ethyl lactate, methyl acetate, ethyl acetate, butyl acetate, methyl pyruvate, ethyl pyruvate, methyl methoxypropionate, and ethyl ethoxypropionate. These organic solvents can be used singularly, or as a mixed solvent of two or more different solvents.

The quantity used of such solvents, for example, in the case in which spin coating is used to form a thick film of at least 10 μm, is preferably sufficient to produce a solid fraction concentration for the chemically amplified positive photoresist composition for a thick film that falls within the range of 30 to 65% by weight. If this solid fraction concentration is less than 30% by weight, then producing a film thickness that is ideal for the manufacture of a connection terminal becomes problematic, whereas if the solid fraction concentration exceeds 65% by weight, then the fluidity of the composition markedly worsens, making handling difficult, and also making it difficult to achieve a uniform resist film using spin coating methods.

Preparation of the positive photoresist composition according to the present invention may be conducted by simply mixing and stirring each of the components described above together using normal methods, or if necessary, by dispersing and mixing the components using a dispersion device such as a dissolver, a homogenizer, or a three roll mill. Furthermore, following the mixing of the components, the composition may also be filtered using a mesh or a membrane filter or the like.

The positive photoresist composition in the present invention is ideal for forming a thick-film photoresist layer with a film thickness of 10 to 150 μm, preferably 20 to 120 μm, and even more preferably 20 to 80 μm, on the surface of a support.

### <Thick Film Photoresist Laminate>

A thick film photoresist laminate in the present invention is provided by a thick film photoresist layer formed from the positive photoresist composition in the present invention laminated on top of the support.

As the support used in the present invention, conventional supports can be used without any particular restrictions, and suitable examples include substrates for electronic componentry, as well as substrates on which a predetermined wiring pattern has already been formed. Specific examples of suitable substrates include metal-based substrates such as silicon, silicon nitride, titanium, tantalum, palladium, titanium-tungsten, copper, chrome, iron, and aluminum, as well as glass substrates. Suitable materials for the wiring pattern include copper, solder, chrome, aluminum, nickel, and gold.

The positive resist composition in the present invention provides a resist pattern with excellent verticalness of the shape which causes less undercutting phenomenon to occur, for example, at the interface between a pattern and a substrate if the material of surface forming a photoresist layer are the material above.

The thick film photoresist laminate described above can be manufactured using the method described below for example.

Namely, a solution of a chemically amplified positive photoresist composition for a thick film prepared in the manner described above is applied to a support, and heating is used to remove the solvent and form the desired coating. The application of the solution to the support can be conducted using a method such as spin coating, slit coating, roll coating, screen printing, or an applicator-based method. The prebake conditions used for a coating of a composition of the present invention may vary depending on factors such as the nature of each of the components within the composition, the blend proportions used, and the thickness with which the composition is applied, although typical conditions involve heating at 70 to 150° C., and preferably at 80 to 140° C., for a period of 2 to 60 minutes.

The film thickness of a thick-film photoresist layer of the present invention is typically within the range of 10 to 150 μm, preferably 20 to 120 μm, and even more preferably 20 to 80 μm.

### <Resist Pattern Forming Method>

Subsequently, in order to form a resist pattern using the thus produced thick film photoresist laminate, the thick film photoresist layer is selectively irradiated (exposed), through a mask with a predetermined pattern, with active light or radiation, such as ultraviolet light of wavelength 300 to 500 nm or visible light. The exposed portions of the thick film photoresist layer alter the alkali solubility.

In this specification, “active light” describes light rays that activate the acid generator, thus causing the generation of acid. As the light source for the active light or radiation, a low pressure mercury lamp, high pressure mercury lamp, ultra high pressure mercury lamp, metal halide lamp, or argon gas laser or the like can be used. In this specification, the term “radiation” refers to ultraviolet radiation, visible light, far ultraviolet radiation, X-rays, electron beams, and ion beams and the like. The radiation exposure dose varies depending on the nature of each of the components within the composition, the blend proportions used, and the thickness of the coating, although in those cases where a ultra high pressure mercury lamp is used, a typical exposure dose is within the range of 100 to 10,000 mJ/cm².

Subsequently, following exposure, a developing treatment is conducted. After the exposure, before the developing treatment, it is preferable to promote diffusion of the acid by post exposure baking (PEB). The positive photoresist composition in the present invention can conduct the PEB treatment in mild conditions. For example, diffusion of the acid can be promoted by heating at 70 to 120° C. for 1 to 10 minutes. In addition, a thick film resist pattern can be provided by conducting the developing treatment in a condition of being kept for 30 to 300 minutes at normal temperature following exposure without being heated.

In the developing treatment, by using a predetermined aqueous alkali solution as the developing solution, the unnecessary portions of the resist layer are then dissolved and removed, thus yielding a predetermined resist pattern. Suitable examples of the developing solution include aqueous solutions of alkali materials such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, 1,8-diazabicyclo[5,4,0]-7-undecene, and 1,5-diazabicyclo[4,3,0]-5-nonane. An aqueous solution prepared by adding a water-soluble organic solvent such as methanol or ethanol, or a surfactant to the aqueous solution of any of these alkali compounds may also be used as the developing solution.

The developing time varies depending on the nature of each of the components within the composition, the blend proportions used, and the dried film thickness of the composition, but is typically within the range of 1 to 30 minutes. Furthermore, suitable methods for the developing process include spin methods, dipping methods, puddle methods, and spray developing methods. Following development, the structure is washed under running water for 30 to 90 seconds and is then dried using an air gun, an oven or the like.

Connection terminals such as metal posts and bumps can then be formed by using plating or the like to embed a conductor formed from a metal or the like within the resist-free portions (the portions removed by the alkali developing solution) of the thus obtained resist pattern. There are no particular restrictions on the plating method, and any conventional plating method can be used. As the plating solution, a solder plating solution, a copper plating solution, a gold plating solution, or a nickel plating solution can be favorably used.

Finally, the remaining resist pattern is removed in accordance with conventional methods, using a stripping solution or the like.

The present invention provides a positive photoresist composition which can obtain high sensitivity in forming a thick film resist pattern, a thick film photoresist j laminate using the same, a method for producing a thick film resist pattern, and a method for producing a connecting terminal. As shown in Examples below, the present invention can improve the sensitivity without decreasing the main characteristics such as the compatibility (dispersion stability) of the positive photoresist composition, the coatability, the developability, or resolution. Furthermore, the present invention has excellent verticalness of the thick film resist pattern shape.

The excellent resist pattern can be provided in the case where materials of surface forming a photoresist layer are not only silicon but also a metal surface such as copper, aluminum, nickelic or gold. This is an important and advantageous effect of the positive photoresist composition for a thick film.

### EXAMPLES

### Examples 1 to 4, Comparative Examples 1 and 2

The various components shown in Table 1 below were mixed together in propylene glycol monomethyl ether acetate to form a series of homogeneous solutions (solid content concentration 50% by weight), and each solution was then filtered through a membrane filter with a pore size of 1 μm, thus yielding a positive photoresist composition. The unit of blending quantity shown in Table 1 represents the number of parts by weight.

Each component in Table 1 is as follows.

(A-1): the component (A1) represented by the general formula (A1-9) above. This component is an onium salt-based acid generator having a naphthalene ring at a cation portion.

(B-1): the copolymer of 30000 weight average molecular weight (Mw) which consists of 55 mol % of 1-(2-adamantyloxy) ethyl methacrylate unit represented by the general formula (b1-01-3) above as the structural unit (b1), 30 mol % of 2-ethoxyethyl acrylate unit as the structural unit (b2), 10 mol % of n-butylacrylate unit as the other polymerizable compounds and 5 mol % of acrylic acid unit.

(B-2): the copolymer whose Mw is changed to 100000 in (B-1) above.

(B-3): the copolymer of 30000 Mw whose structural unit (b1) is changed to 55 mol % of 1-(4-oxo-2-adamantyloxy) ethyl methacrylate unit represented by the general formula (b1-01-17) above as the structural unit (b1) in (B-1) above.

(B-4): the copolymer whose Mw is changed to 100000 in (B-3) above.

(B-5): the copolymer of 300000 weight average molecular weight (Mw) which consists of 30 mol % of 2-ethoxyethylethylacrylate unit as the structural unit (b2), 55 mol % of 2-methylcyclohexyl methacrylate unit as the structural unit (b3), 10 mol % of n-butylacrylate unit as the other polymerizable compounds and 5 mol % of acrylic acid unit.

(B-6): the copolymer of 100000 Mw whose structural unit (b3) is changed to 55 mol % of 2-methyl-adamantyl methacrylate unit represented by the general formula (1) below in the (B-5) above.

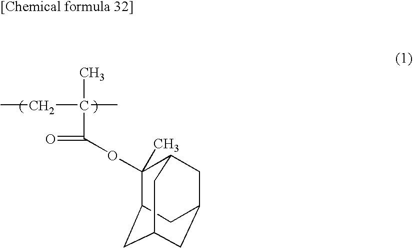

(C-1): the copolymer which consists of 10 mol % of hydroxystyrene unit and 90 mol % of styrene unit.

(C-2): a novolak resin

(D-1): triethanolamine

(D-2): salicylic acid

TABLE 1

| | Exam- | Exam- | Exam- | Exam- | Comparative | Comparative |
|---|---|---|---|---|---|---|
| | ple 1 | ple 2 | ple 3 | ple 4 | Example 1 | Example 2 |
| A-1 | 1 | 1 | 1 | 1 | 1 | 1 |
| B-1 | 40 | | | | | |
| B-2 | | 40 | | | | |
| B-3 | | | 40 | | | |
| B-4 | | | | 40 | | |
| B-5 | | | | | 40 | |
| B-6 | | | | | | 40 |
| C-1 | 10 | 10 | 10 | 10 | 10 | 10 |
| C-2 | 50 | 50 | 50 | 50 | 50 | 50 |
| D-1 | 0.1 | 0.1 | 0.1 | 0.1 | 0.1 | 0.1 |
| D-2 | 0.1 | 0.1 | 0.1 | 0.1 | 0.1 | 0.1 |

### Test Example

The characteristics of the positive photoresist compositions produced in the examples and the comparative examples described above were evaluated in the following manner. The results are shown in Table 2 below.

### (1) Compatibility (Dispersion Stability)

The positive photoresist compositions was stirred for 12 hours at room temperature, and the state of the solution (the state of the dispersion) immediately following completion of the stirring, and the state of the solution upon leaving the solution to stand for a further 12 hours were observed visually. The compatibility was evaluated using the following evaluation criteria.

A: The composition was uniformly dispersed following stirring for 12 hours, but it was visually observed that the composition did not undergo phase separation upon standing for 12 hours.

B: The composition was uniformly dispersed following stirring for 12 hours, but underwent phase separation upon standing for 12 hours.

C: The composition was not uniformly dispersed even after stirring for 12 hours.

### (2) Coatability

Each composition was applied to a 5-inch gold sputtered wafer (a gold substrate) over a period of 25 seconds, using a spinner operating at 1000 rpm, and the applied composition was then pre-baked on a hotplate at 130° C. for 6 minutes to form a formed coating of 20 μm film thickness, and a thick film photoresist laminate was obtained.

Furthermore, a formed coating of 100 μm film thickness was formed in another condition. That is, each composition was applied to a 5-inch gold sputtered wafer over a period of 10 seconds, using a spinner operating at 500 rpm, and the applied composition was then pre-baked on a hotplate at 120° C. for 60 minutes to form a formed coating of 100 μm film thickness, and a thick film photoresist laminate was obtained.

The thus formed coating was inspected visually, and the coatability was evaluated using the following criteria.

A: The formed coating was uniform with no unevenness.

B: The formed coating was not uniform, and displayed poor planarity.

C: The formed coating displayed irregularities such as pinholes and cissing.

### (3) Developability and Resolution

Each thick film photoresist laminate formed in the same manner as the test of coatability above was selectively exposed with ultraviolet radiation through a pattern mask used for measuring resolution, at exposure doses ranging in a stepwise manner from 100 to 10,000 mJ/cm², using an aligner (trademark; PLA501F, manufactured by Canon Inc.). Following exposure, the product was heated (PEB) at 80° C. for 5 minutes, and was then developed in a developing solution (trademark: P-7G from the PMER series, manufactured by Tokyo Ohka Kogyo Co., Ltd.).

The developed product was washed under running water, and blown with nitrogen to yield a pattern-wise cured product. This cured product was inspected under a microscope, and the developability and resolution were evaluated using the following criteria.

Furthermore, with respect to the compositions according to Examples 1 to 4, pattern-wise cured products were obtained in the same manner as the above method using four kinds of 5-inch sputtered wafers of Si, Cu, Ni and Al.

A: A pattern with an aspect ratio of 2 or greater was generated at one of the above exposure doses, and no residues were visible.

C: Either a pattern with an aspect ratio of 2 or greater was not generated, or residues were visible.

The aspect ratio represents the value of (the height of the patterned resist divided by the width of the patterned resist).

### (4) Sensitivity (Photosensitivity)

Coating films of respectively two kinds of film thickness (20 μm and 100 μm) were formed on 5-inch Si, or Au, Cu. Ni or Al sputtered wafers, and each coating film was exposed with ultraviolet radiation in sections, through a pattern mask used for measuring resolution, at exposure doses ranging from 100 to 10,000 mJ/cm², using an aligner (trademark; PLA501F, manufactured by Canon Inc.). Following exposure, the product was heated (PEB) at 80° C. for 5 minutes, and was then developed in a developing solution (trademark: P-7G from the PMER series, manufactured by Tokyo Ohka Kogyo Co., Ltd.). The developed product was washed under running water, and blown with nitrogen to yield a pattern-wise cured product.

This cured product was inspected under a microscope, and the minimum exposure dose required to form a pattern with an aspect ratio of 2 or greater, with no visible residues, in other words, the minimum dose required to form a pattern, was measured. The sensitivity (photosensitivity) was evaluated using the following evaluative criteria.

< In the Case of Coating Films with a Film Thickness of 20 μm>

A: The minimum exposure to form a resist pattern was 300 mJ/cm² or less.

B: The minimum exposure to form a resist pattern was greater than 300 mJ/cm² and less than 600 mJ/cm².

C: The minimum exposure to form a resist pattern was 600 mJ/cm² or more.

< In the Case of Coating Films with a Film Thickness of 100 μm>

A: The minimum exposure to form a resist pattern was 2500 mJ/cm² or less.

B: The minimum exposure to form a resist pattern was greater man 2500 mJ/cm² and less than 5000 mJ/cm².

C: The minimum exposure to form a resist pattern was 5000 mJ/cm² or more.

### (5) Verticalness of the Pattern Shape

The cross-section shape of resist pattern formed in the above developability and resolution test was observed by a cross-section SEM.

As a result, all of the resist patterns obtained in Examples 1 to 4 and Comparative Examples 1 and 2 have excellent verticalness of the pattern (cross-section rectangularity).

TABLE 2

| | Film | | | | | Comparative | Comparative |
|---|---|---|---|---|---|---|---|
| | thickness | Example 1 | Example 2 | Example 3 | Example 4 | Example 1 | Example 2 |
| Compatibility | — | A | A | A | A | A | A |
| Coatability | 20 μm | A | A | A | A | A | A |
| | 100 μm | A | A | A | A | A | A |
| Developability | 20 μm | A | A | A | A | A | A |
| and | 100 μm | A | A | A | A | A | A |
| resolution | | | | | | | |
| Sensitivity | 20 μm | A | A | A | A | B | B |
| | 100 μm | A | A | A | A | B | B |

As shown in Test Examples above, positive photoresist compositions in the Examples can have improved sensitivity without having a decreased compatibility (dispersion stability), coatability, developability or resolution. Furthermore, the present invention can form a resist pattern with excellent verticalness of the shape.

### INDUSTRIAL APPLICABILITY

The present invention provides a positive photoresist composition which can obtain high sensitivity in forming a thick film resist pattern, a thick film photoresist laminate using the same, a method for producing a thick film resist pattern, and a method for producing a connecting terminal.

1. A positive photoresist composition used to form a thick film resist pattern on a support, comprising:
(A) a compound that generates acid on irradiation with active light or radiation and (B) a resin that displays increased alkali solubility under the action of acid, wherein
said component (B) comprises a resin (B1) which has a structural unit (b1) derived from an acrylate ester, in which a hydrogen atom of a carboxyl group has been substituted with an acid dissociable, dissolution inhibiting group represented by a general formula (I) shown below: 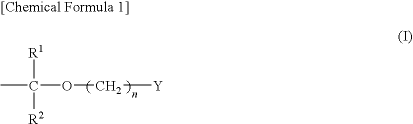
[wherein, Y represents an aliphatic cyclic group or an alkyl group which may comprise a substituent group; n represents either 0 or an integer from 1 to 3; R¹ and R² each independently represents a hydrogen atom or a lower alkyl group of 1 to 5 carbon atoms].

2. The positive photoresist composition according to claim 1, wherein said structural unit (b1) comprises either one, or two or more selected from the group consisting of a structural unit represented by the general formula (b1-01) and a structural unit represented by the general formula (b1-02): 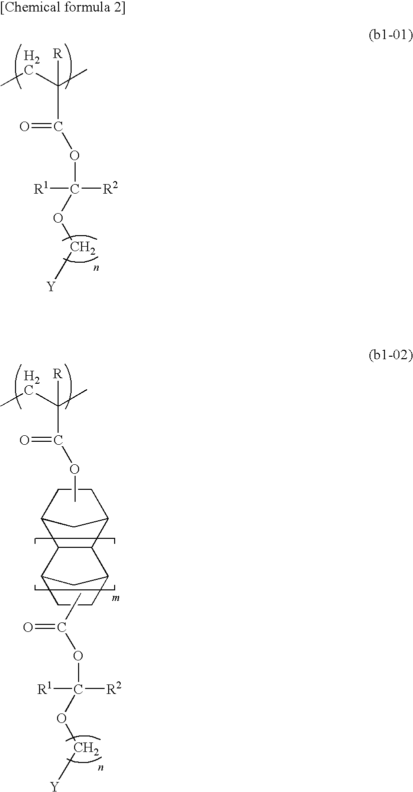
[wherein, Y represents an aliphatic cyclic group which may comprise a substituent group or an alkyl group; n represents either 0 or an integer from 1 to 3; m represents 0 or 1; R each represents, independently, a hydrogen atom, a lower alkyl group of 1 to 5 carbon atoms, a fluorine atom or a fluorinated lower alkyl group of 1 to 5 carbon atoms; R¹ and R² each represents, independently, a hydrogen atom or an lower alkyl group of 1 to 5 carbon atoms].

3. The positive photoresist composition according to claim 1, further comprising an alkali-soluble resin (C).

4. The positive photoresist composition according to claim 1, further comprising an acid diffusion control agent (D).

5. A thick film photoresist laminate, wherein a support and a thick film photoresist layer with a film thickness of 10 to 150 μm comprising the positive photoresist composition according to claim 1 is laminated.

6. A method for producing a thick film resist pattern comprising:
laminating for producing the thick film photoresist laminate according to claim 5,
exposing for selectively irradiating the thick film photoresist laminate with active light or radiation, and
developing for producing a thick film resist pattern following the exposure.

7. A method for producing a connecting terminal comprising:
forming a connection terminal formed from a conductor on a resist-free portion of a thick film resist pattern produced using the method for producing a thick film resist pattern according to claim 6.
